(19) United States
(12) Patent Application Publication
(10) Pub. No.: US 2015/0000726 A1
(43) Pub. Date: Jan. 1, 2015

(54) SOLAR PANEL STRUCTURE

(71) Applicant: HSUAN-YEH HUANG, Tainan (TW)

(72) Inventor: HSUAN-YEH HUANG, Tainan (TW)

(21) Appl. No.: 14/276,771

(22) Filed: May 13, 2014

(30) Foreign Application Priority Data
Jun. 26, 2013 (TW) 102211986

(51) Int. Cl. H01L 31/042

(52) U.S. Cl. CPC H01L 31/0422
USPC 136/251

(57) ABSTRACT

A solar panel structure includes a seat and a plurality of solar panels. The seat includes a recess area which has an opening and at least one inclined plane formed in the recess area. The solar panels are laid on the inclined plane. Hence the solar panels have a total area greater than the area of the opening. As a result, given a same size of land being occupied, the solar panels have a greater light receiving area to increase total electric power generation capacity.

### FIELD OF THE INVENTION

The present invention relates to a solar panel structure and particularly to a solar panel structure that can increase total spread area of solar panels.

### BACKGROUND OF THE INVENTION

With growing popularity of green energy sources in recent years solar energy has become an important usable energy resource that is eco-friendly and easy to get. However, the efficiency of converting solar energy to electric power by solar panels is affected by many factors, such as their material characteristics, structure, installation environments and the like. The general solar panel is formed in a flat type such that a plurality of solar panels can be laid and juxtaposed in a flat manner to collect sunlight. At present, the solar panel conversion efficacy still has room for improvement. How to increase light receiving area of the solar panels in a limited site is an issue commonly encountered in the industry and a goal this invention aims to pursue.

In 2007 wafers made at the size of six inches are the mainstream used in solar energy photoelectric equipments. Nowadays some companies have developed products based on wafers at the size of eight inches. In theory, under projection of a same solar power density (mW/cm²), and with N-type semiconductor and P-type semiconductor (or N-P semiconductors in short hereinafter) on the solar panel formed at the same size and light receiving area, same amount of photo current (Iₚₕ) can be produced, and total current being generated is I=Iₚₕ−I_{D}−I_{R}−(V+IRₛ)/Rₛₕ; where I_{D} is injection current, I_{R} is recombination current, Rₛₕ is shunt resistance, Rₛ is series resistance, V is the voltage of solar cell, and Rₛ is generated by transmission loss caused by electrodes.

The solar panels now on the market generally have the main electrode located in the center with electrons moving from two ends to the main electrode. Due to the electrode is relatively long series resistance increases. In the present solar energy application area, many academic institutions focus the research on material improvement aiming to increase solar energy conversion rate to enhance solar panel efficiency. However, research and development of material improvement take longer time. The invention aims to take another approach: under an environment of a given land area, through increasing the spread area of solar panels in a fixed size of the land to increase total electric power capacity generated by the solar panels, and further providing sub-electrodes with shorter lengths and smaller intervals between them to increase electron transmission efficiency and reduce series resistance, and also designing composite solar panels in various shapes other than rectangle to be laid on the solar panel structure, thereby increase total amount of electric power generation.

### SUMMARY OF THE INVENTION

The primary object of the present invention is to provide a solar panel structure to increase total area of solar panels in a limited site to increase total electric power capacity of solar energy.

To achieve the foregoing object the solar panel structure according to the invention includes a seat and a plurality of solar panels. The seat includes a recess area which has an opening and at least one inclined plane in the recess area. The solar panels are spread and laid on the inclined plane so that the total area of the solar panels is greater than the area of the opening. The opening can be formed in a shape such as ellipse, circle, triangle, quadrilateral, rectangle, trapezoid, pentagon, hexagon or polygon. The solar panels also can be formed in a shape such as ellipse, circle, triangle, quadrilateral, rectangle, trapezoid, pentagon, hexagon or polygon. As a result, in the same area of a given site, the solar panel structure of the invention can provide a greater usable holding space to increase light receiving area of the solar panels, thereby to increase electric power capacity generated by the solar panels. Moreover, the solar panel structure of the invention can be assembled in different shapes to meet requirements of various environments and dimensions.

In an embodiment, each solar panel includes at least one solar power unit which contains at least one substrate with N-P semiconductors located thereon, at least one main electrode located at one side of the N-type semiconductor, and a plurality of sub-electrodes spaced from each other between 0.2 cm and 0.3 cm and located on the N-type semiconductor and connected to the main electrode. Each sub-electrode is formed at a length smaller than 3.8 cm. Furthermore, the invention can provide at least two substrates that also can be formed in a shape of triangle or trapezoid. The N-P semiconductors are located on the substrate and electrically connected on the backside of the substrate in parallel or series to a circuit extended from the main electrode. The solar power units also can be assembled to form the solar panels with different shapes. Thus, the invention, by providing the sub-electrodes at a shorter length and a smaller interval between them, can reduce current transmission loss between the N-P semiconductors, thereby reduce series resistance Rₛ. Moreover, through designing composite solar panels formed in different shapes other than rectangle and laid on the seat, total electric power generation capacity can be increased.

The foregoing, as well as additional objects, features and advantages of the invention will be more readily apparent from the following embodiments and detailed description, which proceeds with reference to the accompanying drawings.

### BRIEF DESCRIPTION OF THE DRAWINGS

FIG. 1A is an exploded view of a first embodiment of the solar panel structure of the invention.

FIG. 1B is a sectional view of the first embodiment of the solar panel structure of the invention.

FIGS. 2 through 7 are plane views of various solar panels formed according to the first embodiment.

FIG. 8 is a plane view of a large area triangular solar panel formed according to the first embodiment.

FIG. 9A is a perspective view of a solar panel assembly structure formed according to the first embodiment.

FIG. 9B is a sectional view of a solar panel assembly structure formed according to the first embodiment.

FIG. 10A is an exploded view of another type of seat according to the first embodiment of the invention.

FIG. 10B is a sectional view of another type of seat according to the first embodiment of the invention.

FIG. 11A is an exploded view of a second embodiment of the solar panel structure of the invention.

FIG. 11B is a sectional view of the second embodiment of the solar panel structure of the invention.

FIGS. 12 through 14 are plane views of the solar panels formed in various types of trapezoids according to the second embodiment.

FIG. 15A is a perspective view of a solar panel assembly structure formed according to the second embodiment of the invention.

FIG. 15B is a sectional view of a solar panel assembly structure formed according to the second embodiment.

FIG. 16 is a perspective view of a solar panel assembly structure formed according to a third embodiment of the invention.

FIG. 17 is a perspective view of a fourth embodiment of the seat of the invention:

FIG. 18 is a perspective view of a fifth embodiment of the seat of the invention.

FIG. 19 is a plane view of a hexagonal solar panel formed according to the fourth and fifth embodiments of the invention.

### DETAILED DESCRIPTION OF THE PREFERRED EMBODIMENTS

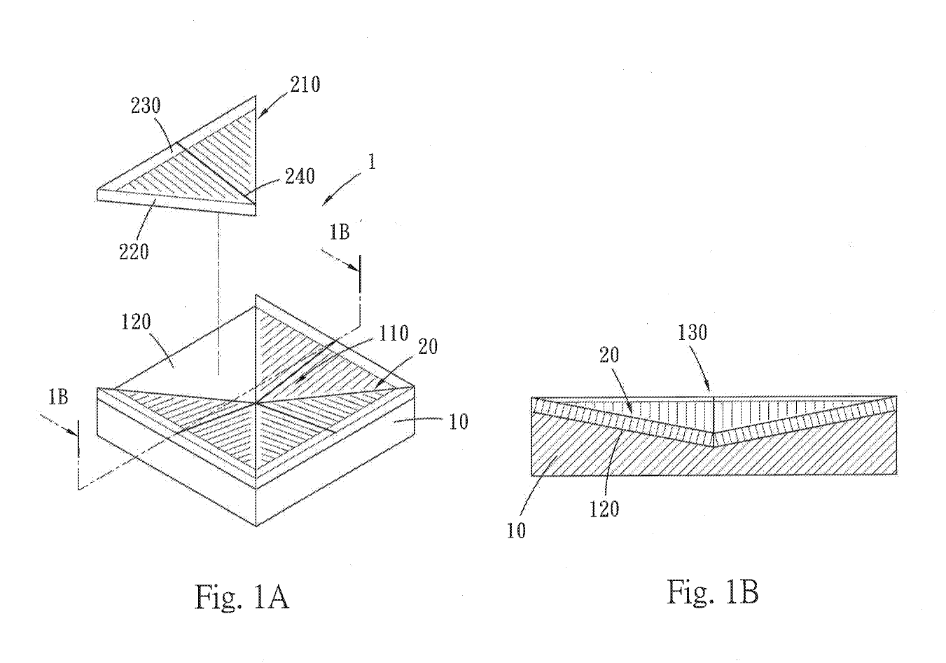

Please refer to FIGS. 1A and 1B for a first embodiment of the solar panel structure of the invention. The solar panel structure 1 includes a seat 10 and a plurality of solar panels 20. The seat 10 mainly aims to hold the solar panels 20 and has a recess area 110 which contains an opening 130 (referring to FIG. 1B). The seat 10 also has at least one inclined plane 120 in the recess area 110. The solar panels 20 are laid on the inclined plane 120. Hence total area of the solar panels 20 in the recess area 110 is greater than the area of the opening 130, thereby can increase the total area of the solar panels 20 in a given site to save the occupied ground area.

In the first embodiment, the seat 10 includes a plurality of inclined planes 120. Any two neighboring inclined planes 120 have their abutting edges joined together. In a specific embodiment, each inclined plane 120 can hold one solar panel 20, while in other embodiments one inclined plane 120 can hold multiple solar panels 20 at the same time, namely multiple solar panels 20 can be spread and laid on the inclined plane 120. The dimension and shape of the solar panels 20 can be designed to match the dimension and shape of the inclined plane 120. In another embodiment the solar panels 20 can be formed in a same shape or different shapes, i.e. some have the same shape while some others are different in shapes. In FIG. 1A the opening 130 of the seat 10 is rectangular, and four inclined planes 120 are provided each is formed in a triangular shape. Hence, as shown in FIG. 1B, the solar panel 20 laid on the inclined plane 120 also is formed in a triangular shape to match each other. However, the embodiment depicted in FIGS. 1A and 1B merely serves for illustrative purpose and is not the limitation of the invention. In other selected embodiments, the opening 130 also can be formed in other shapes such as ellipse, circle, triangle, quadrilateral, rectangle, trapezoid, pentagon, hexagon or polygon. In addition, the solar panels 20 also can be formed in a shape of ellipse, circle, triangle, quadrilateral, rectangle, trapezoid, pentagon, hexagon or polygon, but this is not the limitation of the invention.

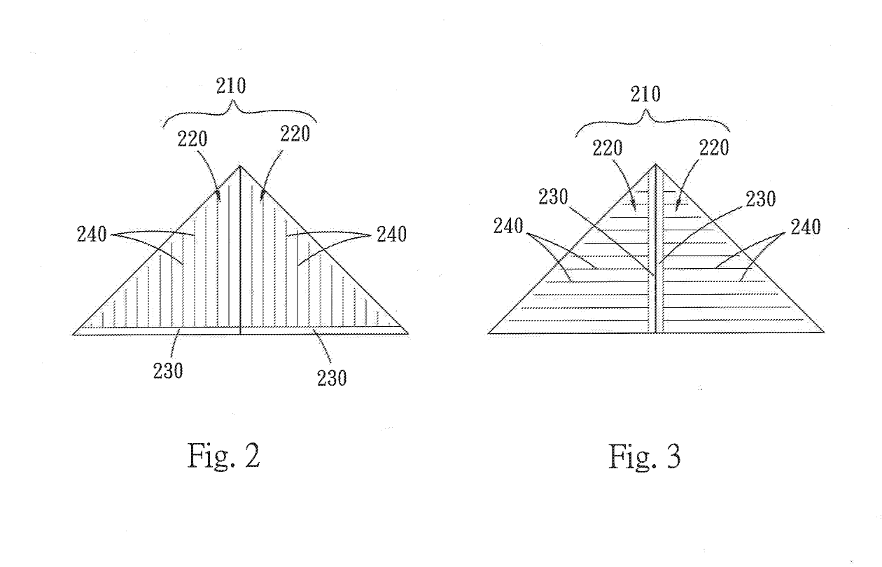

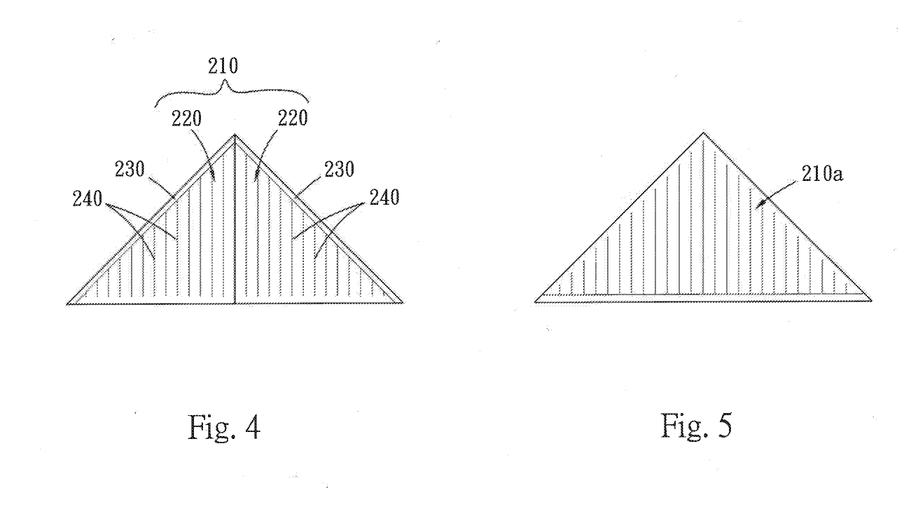

More specifically, each solar panel 20 contains at least one solar power unit 210. Also referring to FIGS. 1A and 2, the solar power unit 210 includes two sets of substrates 220 that are congruent triangles, a main electrode 230 and a plurality of sub-electrodes 240. Each substrate 220 has N-P semiconductors located thereon. The substrate 220 is formed in an isosceles right triangle in this embodiment. The main electrode 230 is located at one lateral side of the N-type semiconductor and electrically connected on the backside of the substrate 220. The main electrodes 230 on the two isosceles right triangles have circuits extended and connected electrically to each other, or as shown in FIG. 3, the main electrodes 230 of the substrates 220 are juxtaposed in an adjoining manner. The electric connection of the main electrodes 230 can be series or parallel according to requirements of voltage and current specification and has to match the electrodes on the backside, details are omitted herein); or as shown in FIG. 4, the main electrodes 230 can also be located respectively on the hypotenuses of the isosceles triangles. Each sub-electrode 240 is formed at a length smaller than 3.8 cm. The sub-electrodes 240 are spaced from each other at an interval between 0.2 cm and 0.3 cm on the N-type semiconductor, and are connected to the main electrode 230.

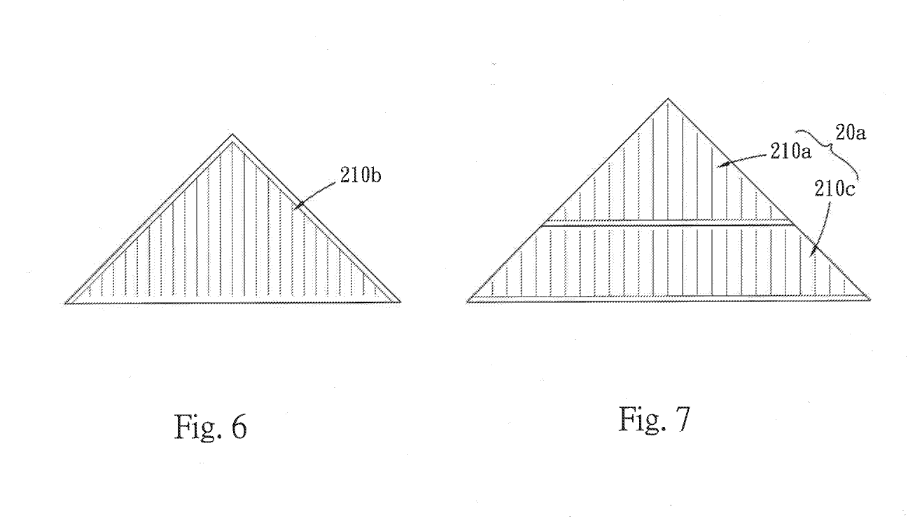

The solar panel of the invention can also include a plurality of solar power units with different structures as the first embodiment shown in FIGS. 5 through 7. The solar panel 20 depicted in FIG. 2 can also be replaced by a single triangular solar power unit 210a illustrated in FIG. 5. The solar panel 20 depicted in FIG. 3 also can be implemented by a single triangular solar power unit 210b shown in FIG. 6. Moreover, the solar power unit 210a shown in FIG. 5 also can be assembled with another solar power unit 210c formed in a trapezoidal shape to become another triangular solar panel 20a with a greater size.

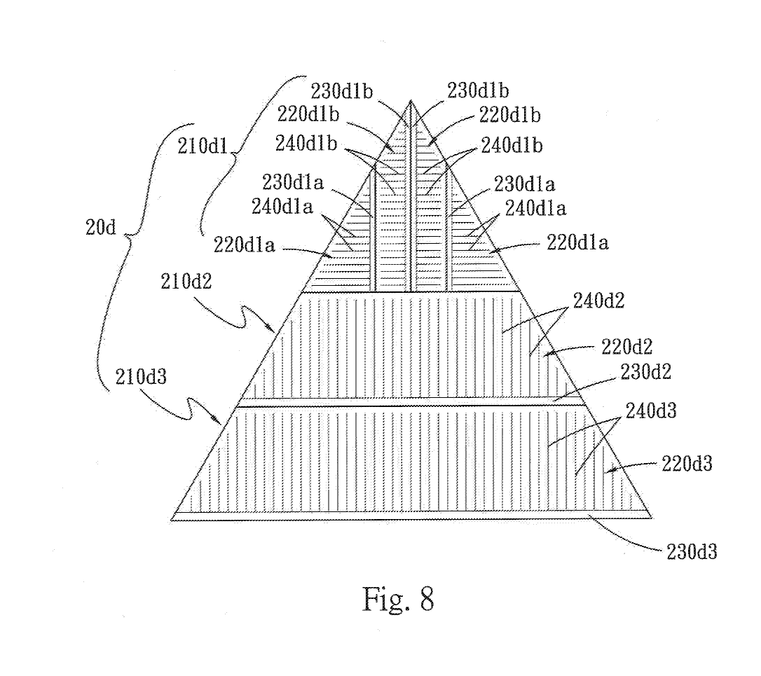

In addition, the invention has limits on the length of the electrodes on the solar power unit. In the event that to form a solar panel with a greater area is desired, different arrangements can be adopted. FIG. 8 illustrates another solar panel 20d formed at a greater area that adopts the first embodiment. The solar panel 20d includes a first unit 210d1, a second unit 210d2 and a third unit 210d3. The first unit 210d1 includes two substrates 220d1a formed in triangles and two other substrates 220d1b formed in trapezoids, hence total four substrates are included with the main electrodes 230d1a and 230d1b located at one side of the N-type semiconductor to connect to the sub-electrodes 240d1a and 240d1b; and the second unit 210d2 and third unit 210d3 are formed respectively in trapezoid. The first unit 210d1 has a triangular substrate 220d1a and a trapezoidal substrate 220d1b on the left side to form parallel electrical connection on the backside of the substrates through the main electrodes 230d1a and 230d1b; the parallel coupled substrates on the left side are further coupled in parallel with another set of substrates on the right side that have another triangular substrate 220d1a and another trapezoidal substrate 220d1b that also are coupled in parallel in advance, thus formed the first unit 210d1. The first unit 210d1, second unit 210d2 and third unit 210d3 can be designed with a same short circuit current, and then these three units can be electrically connected in series. They also can be designed with different short circuit currents, and then they can be electrically coupled in parallel. Hence depending on the required voltage and current, various designs can be made to form the triangular solar panel 20d with a greater area.

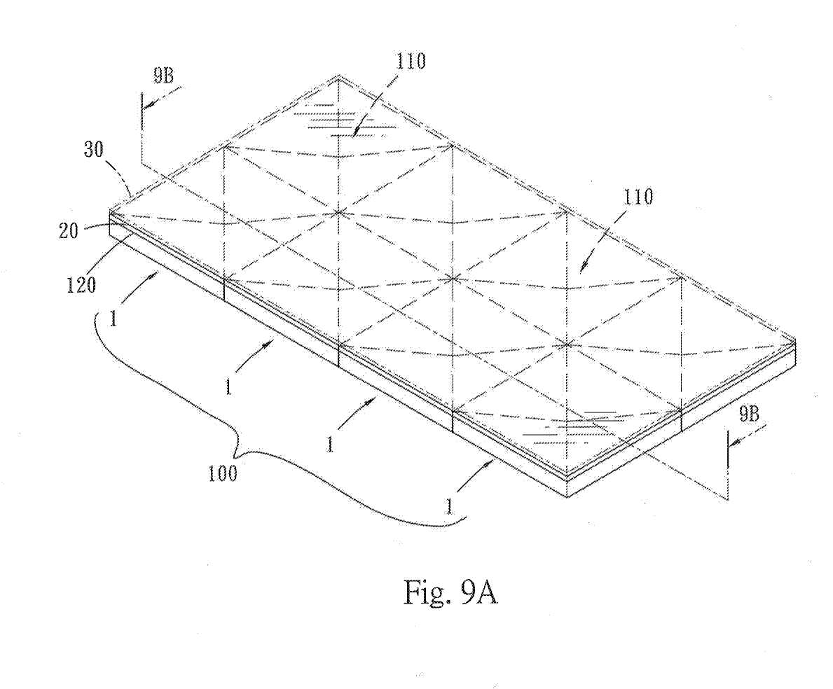

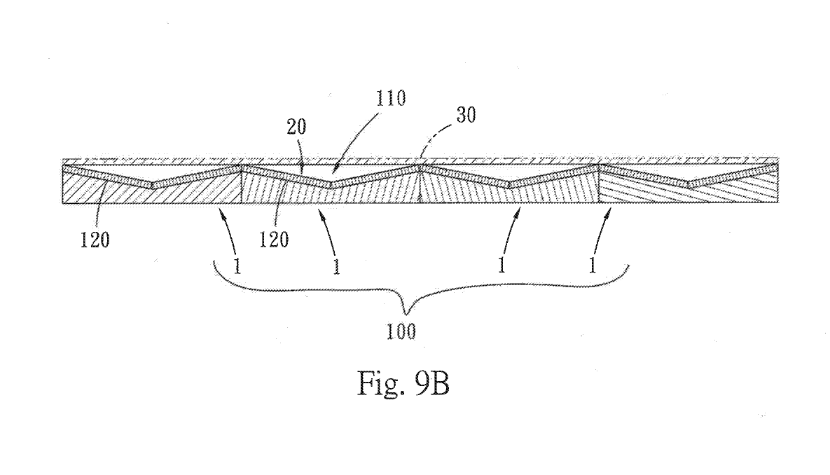

Please refer to FIGS. 9A and 9B for a solar panel assembly structure formed according to the first embodiment. In this embodiment, the solar panel structures 1 can be connected with each other to form a solar panel assembly structure 100 with a larger area. In one embodiment, the solar panel assembly structure 100 can be covered by a protective layer 30 on the top surface thereof to protect the solar panels 20 from being damaged by sunshine, rain or dirt. In other embodiments the protective layer 30 can be a reflective layer or fully light permeable layer to enhance sunlight collection efficiency.

In FIG. 9A each recess area 110 includes four inclined planes 120 formed in isosceles triangles at the same size, with the opening of the square recess area 110 formed at a side length about 6 to 7 cm, and can be implemented via the solar panels 20 depicted in FIGS. 2 through 6. In the event that four triangular solar panels with the same size in a square recess area with an opening at a side length about 15 to 18.5 cm (or about 6 to 8 inches) is intended, three solar power units 210d1, 210d2 and 210d3 shown in FIG. 8 can be employed. The inclined plane 120 is inclined against the opening 130 at an angle of 15-50 degrees. With different side lengths of the square recess areas 110, different inclined angles are formed.

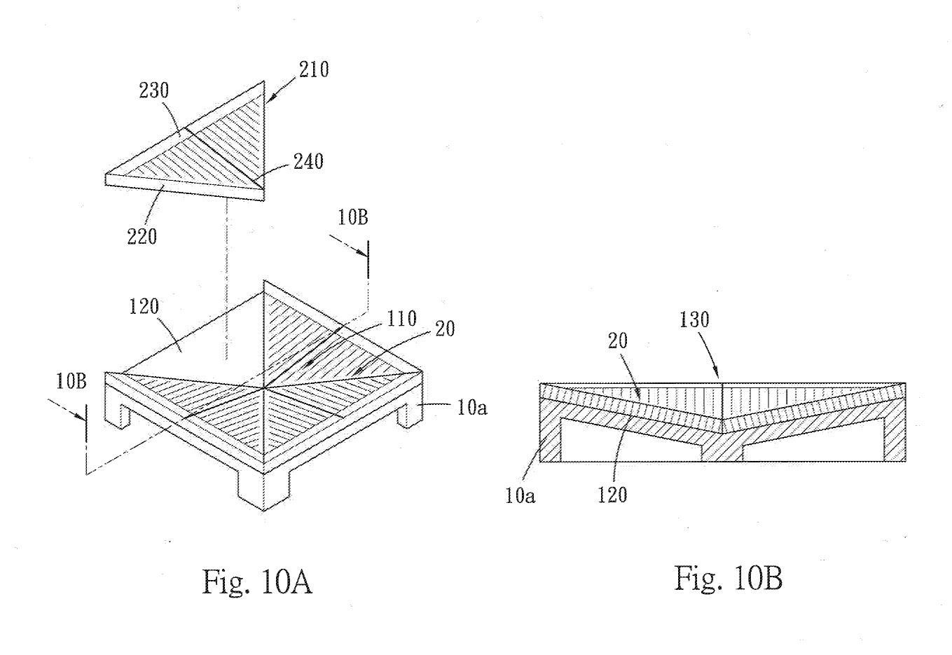

Furthermore, the seat 10 can be formed in other profiles apart from the ones shown in the previous drawings. Please refer to FIGS. 10A and 10B for another type of seat 10a made according to the first embodiment of the solar panel structure. It has brackets at the corners of the solar panels 20 to support the inclined planes 120 and solar panels 20 in the recess area 110.

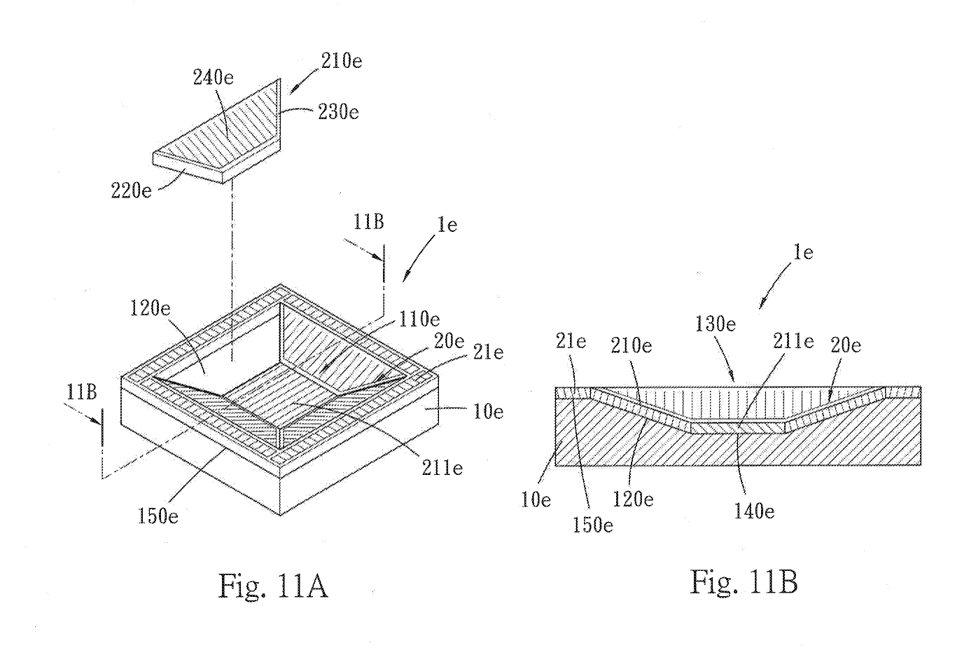

Please refer to FIGS. 11A and 11B for a second embodiment of the solar panel structure 1e of the invention. It includes a seat 10e (referring to FIG. 11B) and a plurality of solar panels 20e. The seat 10e has a recess area 110e which contains an opening 130e, and a bottom plane 140e and at least one inclined plane 120e. The bottom plane 140e is located at the bottom of the recess area 110e. The inclined plane 120e is located in the recess area 110e and adjacent to the bottom plane 140e. The solar panels 20e are laid on the bottom plane 140e and inclined plane 120e and formed in shapes corresponding to that of the bottom plane 140e and inclined plane 120e. As a result, the total area of the solar panels 20e in the recess area 110e is greater than the area of the opening 130e. Hence the total area of the solar panels 20e is greater than the area of a given site where the solar panels 20e are located, and such a design also can save the occupied ground area.

In FIG. 11A, the bottom plane 140e is rectangular, and there are four inclined planes 120e each is formed in a trapezoid. Hence, as shown in FIG. 11B, the solar panels 20e laid on the bottom plane 140e and inclined plane 120e also are formed respectively in a corresponding rectangle and a corresponding trapezoid. However, the embodiment shown in FIGS. 11A and 11B merely serves as an example, and is not the limitation of the invention. The opening 130e can also be formed in a shape such as ellipse, circle, triangle, quadrilateral, rectangle, trapezoid, pentagon, hexagon or polygon, and the bottom plane 140e also can be formed in a shape such as ellipse, circle, triangle, quadrilateral, rectangle, trapezoid, pentagon, hexagon or polygon, that is same as the opening. For instance, in an illustrative case, the opening 130e can be formed in a shape of pentagon, and the bottom plane 140e also can be formed in a shape of a corresponding pentagon, and the inclined plane 120e is connected to the opening 130e and bottom plane 140e. In other embodiments, the inclined plane 120e can be formed in a shape of trapezoid, triangle or quadrilateral, but this is not the limitation of the invention.

Please refer to FIGS. 11A and 11B again, the seat 10e further has at least one side frame 150e at one side of the opening 130e. The side frame 150e is a plane and can hold extra solar panels 21e in addition to the solar panels 20e laid on the bottom plane 140e and inclined plane 120e. Moreover, the solar panel 21e can be formed in a dimension and shape matching the dimension and shape of the side frame 150e. In other embodiments, multiple sets of extra solar panels 21e can be deployed and laid on the side frame 150e, and each extra solar panel 21e can be formed in a shape different from that of the side frame 150e and in a dimension smaller than that of the side frame 150e. Although the embodiment shown in FIGS. 11A and 111B has the side frame 150e on the seat 10e, in other embodiments the seat 10e can be formed without the side frame 150e. For instance, the seat 10 shown in FIGS. 1A and 1B does not have side frame, but it also can have side frame to hold extra solar panels.

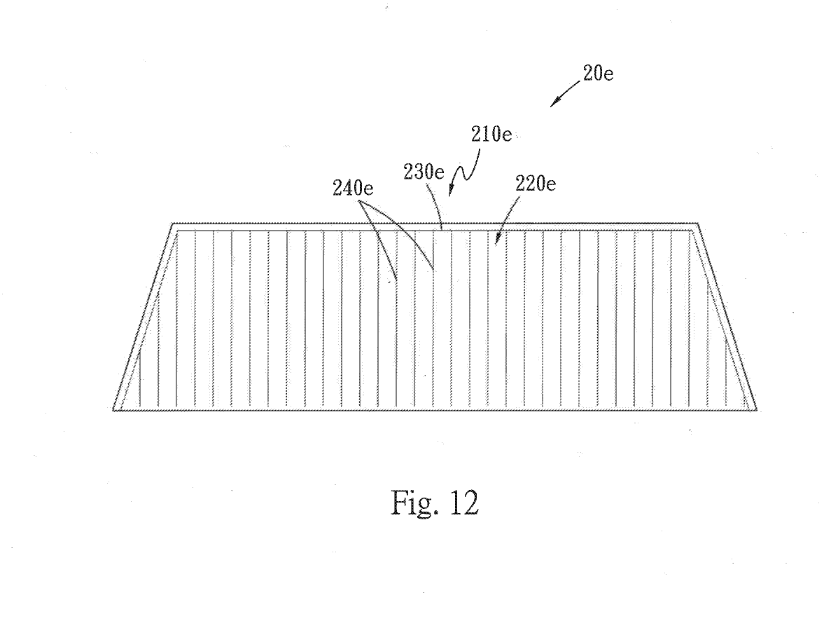

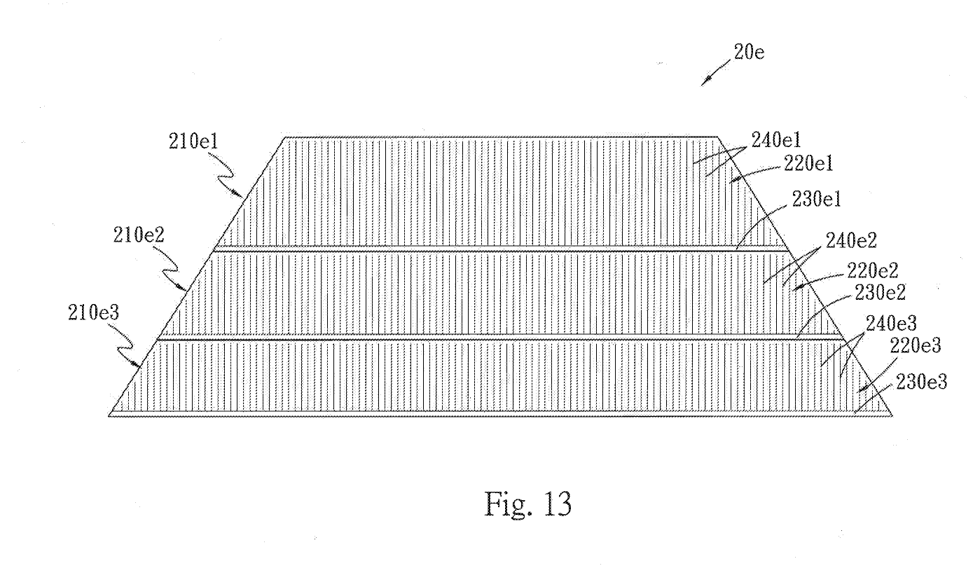

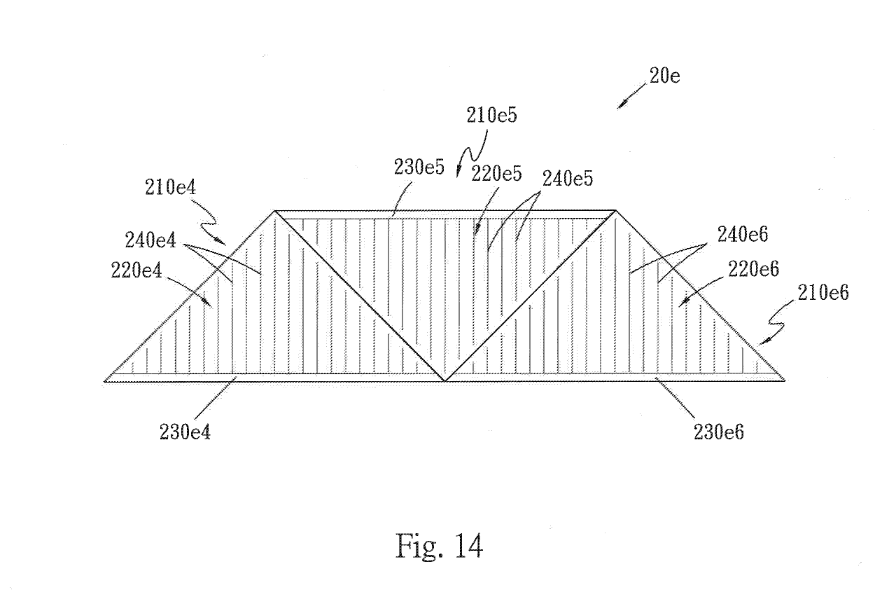

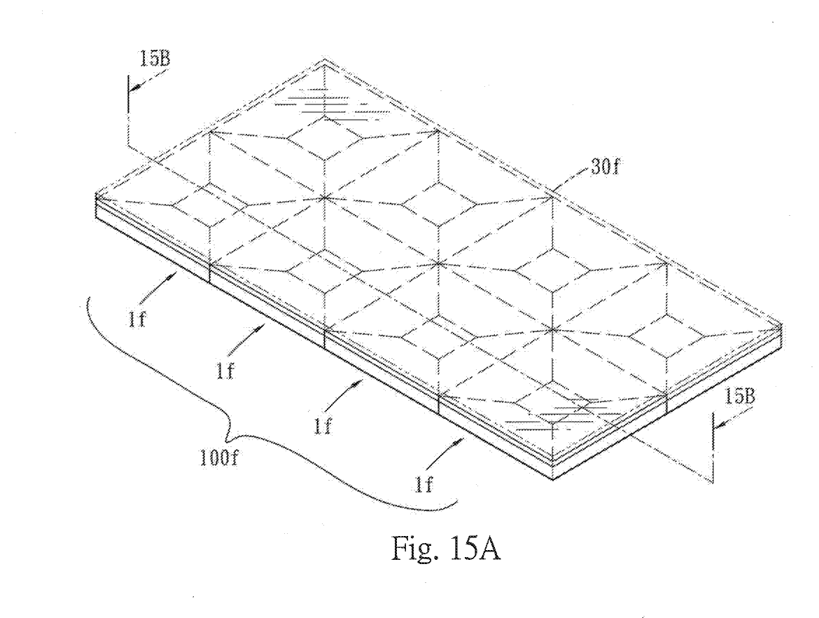

Please refer to FIGS. 12 through 14 for the plane views of solar power units in a second embodiment of the invention. They are corresponding to the structure of the solar panels 20e shown in FIGS. 11A and 11B. In this embodiment, the solar panel 20e is a trapezoidal solar power unit 210e (referring to FIG. 12) which includes a trapezoidal substrate 220e, a main electrode 230e located at an upper side and two lateral sides of the solar power unit 210e, and a sub-electrode 240e connected to the main electrode 230e. Or as shown in FIG. 13, the solar panel 20e can include three solar power units 210e1, 210e2 and 210e3 that have respectively a substrate 220e1, 220e2 and 220e3 formed in the same size and shape of trapezoid. The substrates 220e1, 220e2 and 220e3 have respectively N-P semiconductors located thereon, and also have respectively a main electrode 230e1, 230e2 and 230e3 at one side of the N-type semiconductor of the substrate 220e1, 220e2 and 220e3 to connect to the sub-electrode 240e1, 240e2 and 240e3. The solar power units 210e1, 210e2 and 210e3 can be electrically connected with each other in series or parallel on the backside of the substrates through circuits extended from the main electrodes according to requirements. In this embodiment, the -solar panel is formed in a trapezoidal shape at a greater size. The solar panel 20e of the second embodiment can also be formed in another structure as shown in FIG. 14, in which the solar panel 20e includes three solar power units 210e4, 210e5 and 210e6 that have respectively a triangular substrate 220e4, 220e5 and 220e6 with the same size and shape, and also have N-P semiconductors with the same size and shape located on the substrates 220e4, 220e5 and 220e6, and a main electrode 230e4, 230e5 and 230e6 at one side of the N-type semiconductor connected to the sub-electrode 240e4, 240e5 and 240e6. The solar power units 210e4, 210e5 and 210e6 are electrically connected with each other to form a trapezoidal solar panel 20e with a greater area.

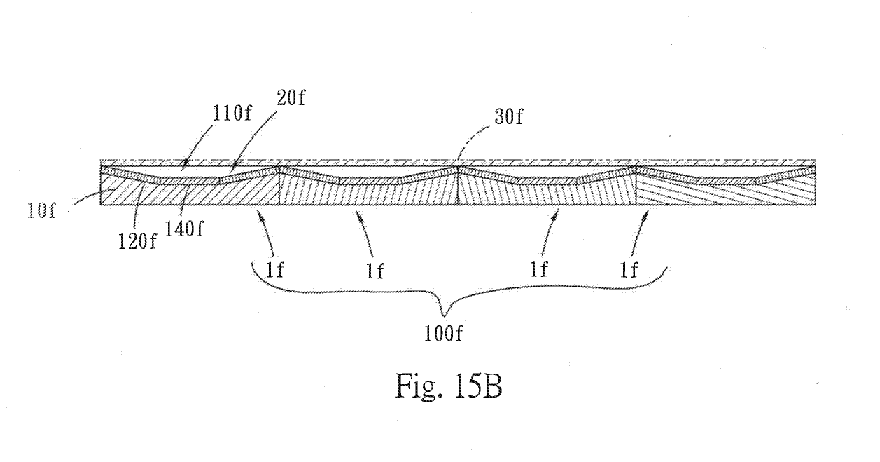

Please refer to FIGS. 15A and 15B for a solar panel assembly structure formed according to the second embodiment. In this embodiment the solar panel structure 1f differs from the solar panel structure 1e shown in FIG. 11A merely by having no side frame 150e. All other structure is the same, and details of the structure are omitted herein. The solar panel structures 1f are connected with each other to form a solar panel assembly structure 100f with a greater area. FIG. 15A shows that the solar panel structures if include eight sets, but the number and arrangement are not the limitation. Please refer to FIG. 15B, like the first embodiment, the solar panel assembly structure 100f can also be covered by a protective layer 30f on the top surface thereof to protect the solar panels 20f from being damaged by sunshine, rain or dirt. In one embodiment the protective layer 30f can also be a reflective layer or fully light permeable layer to enhance sunlight collection efficiency.

The opening of the recess area 110f of the solar panel structure 1f is a square, and the four inclined planes 120f in the recess area are trapezoids. The bottom plane 140f is a square connected to the trapezoidal inclined planes 120f. During implementation the trapezoidal solar panels can be laid on the four trapezoidal inclined planes in the recess area of the same size, and a square solar panel also is laid on the bottom surface of the recess area. The trapezoidal inclined plane is inclined against the opening at an angle of 15-55 degrees.

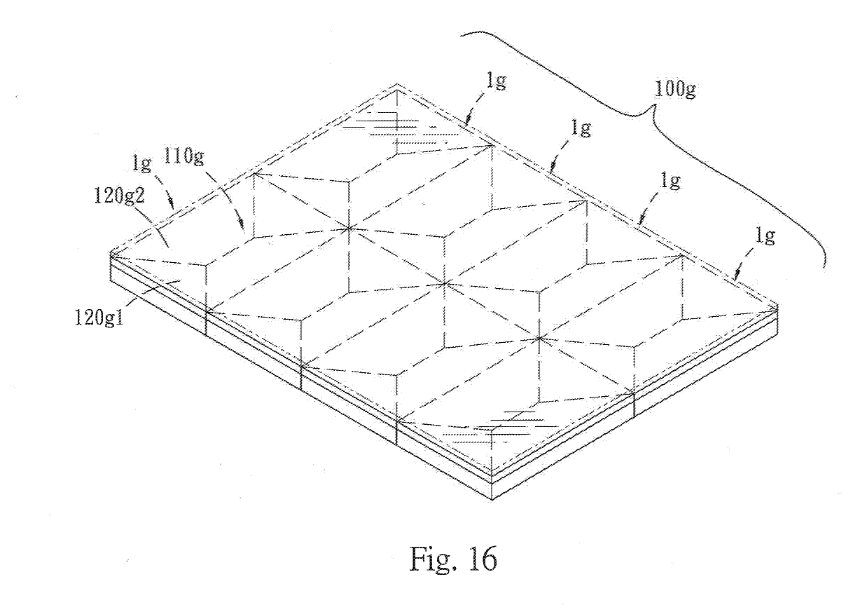

Please refer to FIG. 16 for a solar panel assembly structure formed according to a third embodiment of the invention. In this embodiment, multiple sets of solar panel structures are coupled together to form a solar panel assembly structure 100g. The solar panel structure differs from the previous embodiments merely by the shape of the seat 1g. As shown in the drawings, the solar panel structure 1g is formed by coupling triangular solar panels 20 like that in FIG, 1A and trapezoidal solar panels 20e like that in FIG. 11A together. While eight solar panel structures 1g are shown in FIG. 16, the number and arrangement of the solar panel structures being deployed are determined by different requirements. In this embodiment each solar panel structure 1e has a rectangular opening, and each recess area 110g contains two triangular inclined planes 120g1 and two trapezoidal inclined planes 120g2. During implementation, the solar power units formed in triangular and trapezoidal shapes as previously discussed can be deployed and laid on the inclined planes 120g of the recess area 110g. The triangular inclined plane 120g1 is inclined against the opening at an angle of 20-60 degrees; and the trapezoidal inclined plane 120g2 is inclined against the opening at another angle of 10-48 degrees.

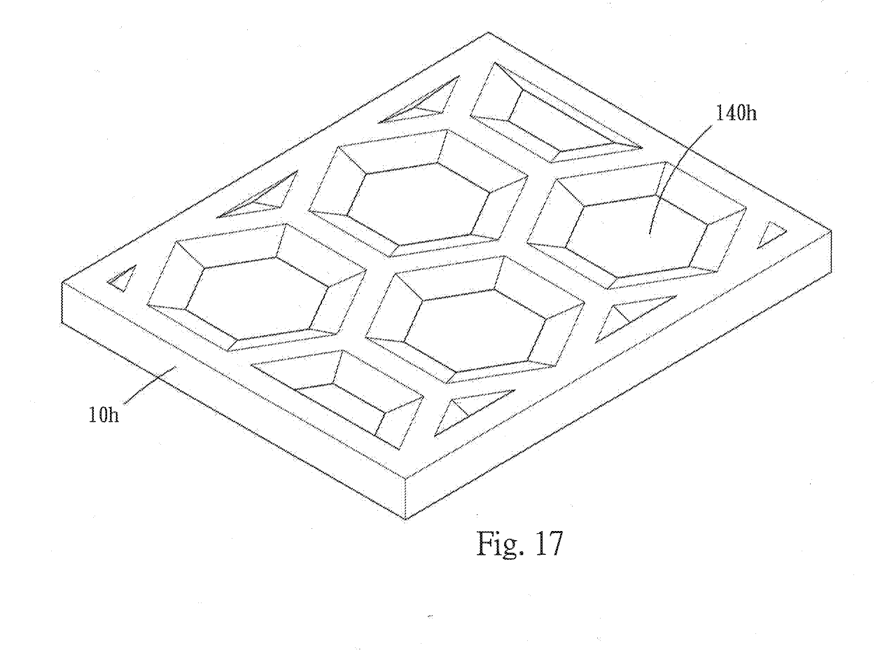

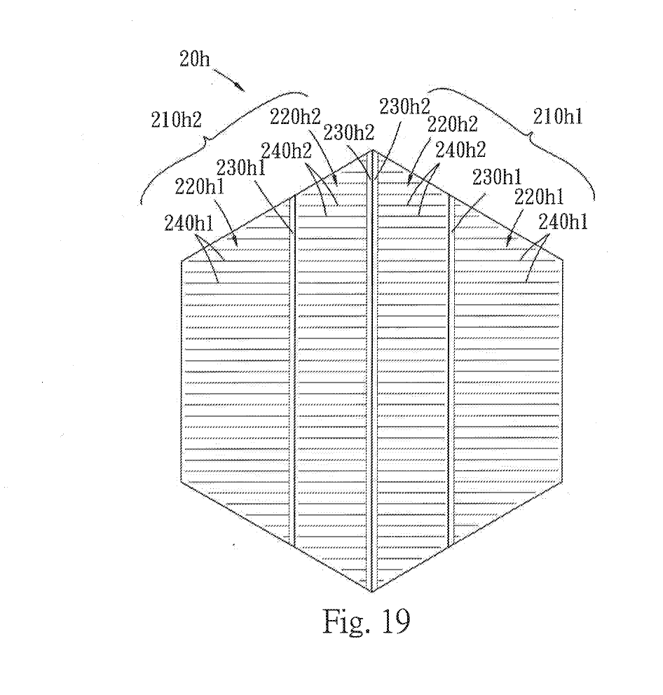

Please refer to FIGS. 17 through 19 for two types of seats and a solar panel used on a fourth and a fifth embodiments of the invention. The seats 10h and 10i aim to hold hexagonal solar panels 20h shown in FIG. 19, the triangular solar panels 20 in the first embodiment or the trapezoidal solar panels 20e in the second embodiment that are coupled to form the solar panel assembly structure. However, the fourth and fifth embodiments mainly aim to indicate that the invention can assemble various shapes of solar panel structures to meet the requirements of various site profiles and sizes, and are not limited to the combinations of hexagonal and triangular shapes.

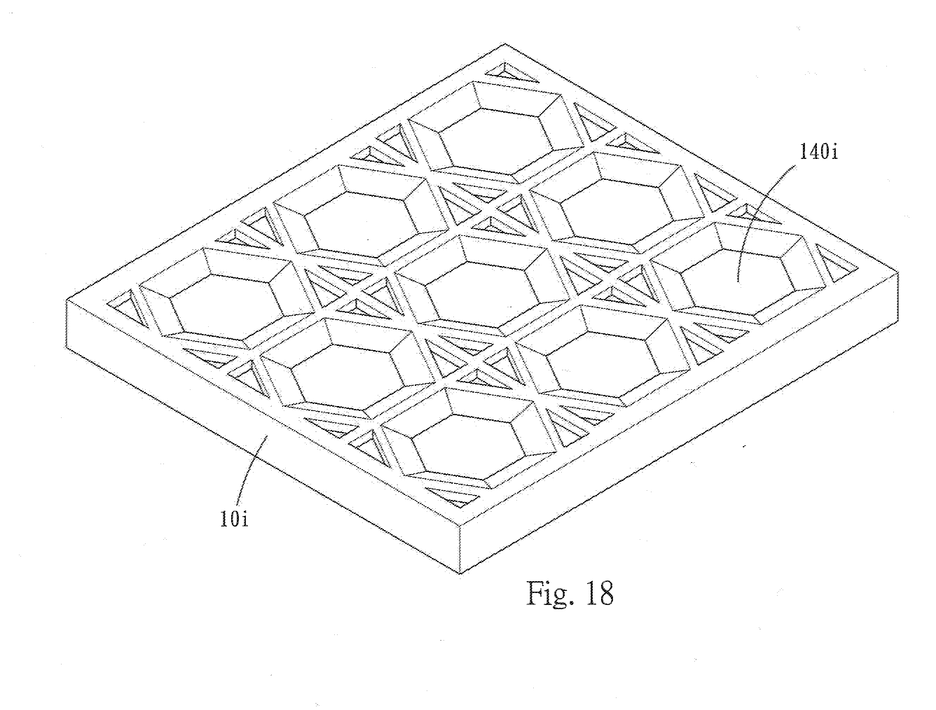

Please refer to FIG. 19 for the regular hexagonal solar panel 20g. In FIGS. 17 and 18, the seats 10h and 10i have respectively a hexagonal bottom plane 140h and 140i to hold the solar panel 20h which includes a solar power unit 210h1 and another solar power unit 210h2 that include respectively two trapezoidal substrates 220h1 with the same size and shape, and other two trapezoidal substrates 220h2 with the same shape, and N-P semiconductors with the same shape located on the substrates 220h1 and 220h2, and main electrodes 230h1 and 230h2 located respectively at one side of the N-type semiconductor to connect to the sub-electrodes 240h1 and 240h2. In the event that the start voltage and short circuit current are being designed the same, the circuits extended from the main electrodes 230h1 and 230h2 on the backside of the four substrates can be coupled in parallel or series. The parallel coupling can increase the current, while series coupling can increase the voltage. The assembly of these two trapezoidal solar power units can form a hexagonal solar panel structure with a greater size.

While various types of embodiments of the solar panel structures of the invention have been discussed above, it is to be noted that they can be implemented through the same approach, i.e. place the main electrode at one side of the N-type semiconductor, connect the sub-electrodes to the main electrode, form the sub-electrodes at a length smaller than 3.8 cm and space sub-electrodes at an interval ranged from 0.2 cm to 0.3 cm. Such solar power units with higher electron transmission efficiency can be assembled to form a solar panel with a greater size, and also can be assembled to form a solar panel in various shapes such as ellipse, circle, triangle, non-rectangular quadrilateral, trapezoid, pentagon, hexagon or polygon.

As a conclusion, the invention employs a seat with a recess area to hold solar panels, hence can increase the holding space of the solar panels without increasing the land area occupied by the entire solar panel structure, thereby increase total light receiving area of the solar panels and increase electric power generated by the solar panel structure per opening unit area. In addition, through assembly of solar panel structures with various shapes, the requirements of varying shapes and sizes in different environments can be fully met. Furthermore, the solar power units with different shapes also can be assembled to form a solar panel structure with a greater size to meet requirements of various voltages and currents. Finally, by providing the sub-electrodes with a shorter length, the series resistance can be reduced and power transmission loss also is decreased so that the solar panel structure of the invention can achieve higher solar energy conversion efficiency.

What is claimed is:

1. A solar panel structure, comprising:
a seat including a recess area with an opening and at least one inclined plane formed in the recess area; and
a plurality of solar panels laid on the inclined plane such that a total area of the plurality of solar panels is greater than an area of the opening.

2. The solar panel structure of claim 1, wherein the seat includes a plurality of inclined planes, any two neighboring inclined planes are connected together through abutting edges thereof.

3. The solar panel structure of claim 1, wherein the inclined plane holds at least one solar panel.

4. The solar panel structure of claim 1, wherein the opening is selectively formed in a shape of circle, ellipse, triangle, quadrilateral, rectangle, trapezoid, pentagon, hexagon or polygon.

5. The solar panel structure of claim 1, wherein the solar panels are selectively formed in a shape of circle, ellipse, triangle, quadrilateral, rectangle, trapezoid, pentagon, hexagon or polygon.

6. The solar panel structure of claim 1, wherein the seat includes at least one side frame at one side of the opening at the top surface thereof to hold the solar panels.

7. The solar panel structure of claim 1, wherein the recess area includes four inclined planes formed in a same triangular shape; wherein the solar panels laid on the triangular inclined planes are inclined against the opening at an angle of 15-50 degrees.

8. The solar panel structure of claim 1, wherein the recess area includes two triangular inclined planes and two trapezoidal inclined planes; wherein the solar panels laid on the triangular inclined planes are inclined against the opening at an angle of 20-60 degrees, and the solar panels laid on the trapezoidal inclined planes are inclined against the opening at another angle of 10-48 degrees.

9. The solar panel structure of claim 1, wherein the recess area includes a bottom plane formed in a shape same as that of the opening to hold at least one solar panel, and the inclined plane is abutted to the bottom plane.

10. The solar panel structure of claim 9, wherein the recess area includes four trapezoidal inclined planes and a rectangular bottom plane; wherein the solar panels laid on the trapezoidal inclined planes are inclined against the opening at an angle of 15-55 degrees.

11. The solar panel structure of claim 1, wherein each of the plurality of solar panels includes at least one solar power unit which includes at least one substrate with N-P semiconductors, at least one main electrode and a plurality of sub-electrodes connected to the main electrode; wherein the main electrode is located at one side of the N-type semiconductor, and each of the plurality of sub-electrodes is formed at a length smaller than 3.8 cm and two neighboring sub-electrodes are spaced from each other at an interval of 0.2-0.3 cm.

12. The solar panel structure of claim 11, wherein the solar power units of the plurality of solar panels are connected in series or in parallel determined by voltage and current specification.

13. The solar panel structure of claim 11, wherein the solar power unit is selectively formed in a shape of ellipse, circle, triangle, non-rectangular quadrilateral, trapezoid or polygon.

14. The solar panel structure of claim 13, wherein three sets of the solar power units form a triangular solar panel with a greater size and are defined as a first unit, a second unit and a third unit; wherein the first unit is a triangular solar power unit, the second unit is a trapezoidal solar power unit and the third unit is another trapezoidal solar power unit, and the first unit includes two triangular substrates and two trapezoidal substrates that are coupled in parallel, and the first unit, the second unit and the third unit are coupled in parallel or in series in a sequence to conform to a voltage and a current required.

15. The solar panel structure of claim 13, wherein the trapezoidal solar power units are arranged to form a trapezoidal solar panel with a greater size and electrically connected in parallel or in series.

16. The solar panel structure of claim 13, wherein the two trapezoidal solar power units are arranged to form a hexagonal solar panel with a greater size and electrically connected in parallel or in series.

17. A solar panel assembly structure, comprising a plurality of solar panel structures that are connected in series or in parallel, each of the plurality of solar panel structures comprising:
a seat including a recess area with an opening and at least one inclined plane formed in the recess area; and
a plurality of solar panels laid on the inclined plane such that a total area of the plurality of solar panels is greater than an area of the opening.
